(19) United States
(12) Patent Application Publication
(10) Pub. No.: US 2021/0352834 A1
(43) Pub. Date: Nov. 11, 2021

(54) ELECTROMAGNETIC SHIELDING FIBER, CABLE AND MANUFACTURING METHOD OF CABLE

(71) Applicant: LUXSHARE PRECISION INDUSTRY Co., Ltd., Shenzhen (CN)

(72) Inventors: HuaBing LI, Shenzhen (CN); Hong CHI, Shenzhen (CN)

(73) Assignee: LUXSHARE PRECISION INDUSTRY Co., Ltd., Shenzhen (CN)

(21) Appl. No.: 17/014,706

(22) Filed: Sep. 8, 2020

(30) Foreign Application Priority Data
May 7, 2020 (CN) 202010377587.3

(51) Int. Cl. H05K 9/00; H01B 13/26; H01B 7/17; H01B 1/22

(52) U.S. Cl. CPC H05K 9/0088; H01B 1/22; H01B 7/17; H01B 13/26

(57) ABSTRACT

The embodiments of the present disclosure provide an electromagnetic shielding fiber, a cable and a cable manufacturing method. The electromagnetic shielding fiber comprises 100 parts by weight of polyester fiber, 40 to 60 parts by weight of copper, 2 to 10 parts by weight of curing agent, 20 to 30 parts by weight of nickel, 5 to 15 parts by weight of microwave absorber, and 2 to 5 parts by weight of dye. The electromagnetic shielding fiber of this disclosure performs excellent electromagnetic shielding and heat dissipation. The cable having the electromagnetic shielding layer made of the electromagnetic shielding layer of the present disclosure performs great electromagnetic shielding and data and signal transmission, and also reduces the costs of products.

### CROSS REFERENCE TO RELATED APPLICATION

This application claims the priority benefit of Chinese Patent Application Serial Number CN202010377587.3, filed on May 7, 2020, the full disclosure of which is incorporated herein by reference.

### BACKGROUND

### Technical Field

The present disclosure relates to the technical field of cable, particularly to an electromagnetic shielding fiber, a cable, and a cable manufacturing method.

### Related Art

With the rapid development of the electronic and communication industry, electronic and electrical devices have been widely used. As conventional electrical equipment having various electronic components emitting electromagnetic radiation, it is crucial to reduce or prevent the electromagnetic radiation of the devices and electromagnetic interference between the devices to improve the safety and reliability of electronic products and devices. This generally requires the establishment of conductive layers in electronic products and devices for electromagnetic shielding.

For cables for data and signal transmission, in order to ensure the transmission performance of the cable under an environment of electromagnetic interference, an electromagnetic shielding layer is provided in the cable. The electromagnetic shielding layer is a metal layer and aluminum foil wrapping on the outside of the conducting wire core to shield electromagnetic interference. However, the conventional electromagnetic shielding layer in the cable cannot completely shield external electromagnetic interference or unused signal interference in practice, indicating a poor electromagnetic shielding of the current electromagnetic shielding layer applied in the cable.

SUMMARY

The embodiments of the present disclosure provide an electromagnetic shielding fiber, a cable and a cable manufacturing method to solve the problem of poor electromagnetic shielding of the electromagnetic shielding layer made of a metal layer and aluminum foil when transmitting data and signals in a cable.

In one embodiment, the electromagnetic shielding fiber comprises 100 parts by weight of polyester fiber, 40 to 60 parts by weight of copper, 2 to 10 parts by weight of curing agent, 20 to 30 parts by weight of nickel, 5 to 15 parts by weight of microwave absorber, and 2 to 5 parts by weight of dye.

In another embodiment, the cable comprises a plurality of conducting wire cores and an electromagnetic shielding layer covering the plurality of conducting wire cores. The electromagnetic shielding layer comprises the electromagnetic shielding fiber according to the above description.

In another embodiment, the cable manufacturing method comprises providing a plurality of conducting wire cores and covering the plurality of conducting wire cores by an electromagnetic shielding layer. The electromagnetic shielding layer comprises the electromagnetic shielding fiber according to the above description.

The embodiments of the present disclosure provides an electromagnetic shielding fiber presenting excellent electromagnetic shielding, which enhances the resistance of cables to electromagnetic interference, and provides excellent heat dissipation, and also reduces cost of materials and processing.

It should be understood, however, that this summary may not contain all aspects and embodiments of the present disclosure, that this summary is not meant to be limiting or restrictive in any manner, and that the disclosure as disclosed herein will be understood by one of ordinary skill in the art to encompass obvious improvements and modifications thereto.

### BRIEF DESCRIPTION OF THE DRAWINGS

The features of the exemplary embodiments believed to be novel and the elements and/or the steps characteristic of the exemplary embodiments are set forth with particularity in the appended claims. The Figures are for illustration purposes only and are not drawn to scale. The exemplary embodiments, both as to organization and method of operation, may best be understood by reference to the detailed description which follows taken in conjunction with the accompanying drawings in which:

FIG. 1 is a cross-sectional view of a cable of one embodiment of the present disclosure;

FIG. 2 is an electromagnetic shielding test chart of the prior art; and

FIG. 3 is an electromagnetic shielding test chart of a cable of one embodiment of the present disclosure.

### DETAILED DESCRIPTION OF THE EMBODIMENTS

The present disclosure will now be described more fully hereinafter with reference to the accompanying drawings, in which exemplary embodiments of the disclosure are shown. This present disclosure may, however, be embodied in many different forms and should not be construed as limited to the embodiments set forth herein. Rather, these embodiments are provided so that this present disclosure will be thorough and complete, and will fully convey the scope of the present disclosure to those skilled in the art.

Certain terms are used throughout the description and following claims to refer to particular components. As one skilled in the art will appreciate, manufacturers may refer to a component by different names. This document does not intend to distinguish between components that differ in name but function. In the following description and in the claims, the terms “include/including” and “comprise/comprising” are used in an open-ended fashion, and thus should be interpreted as “including but not limited to”. “Substantial/substantially” means, within an acceptable error range, the person skilled in the art may solve the technical problem in a certain error range to achieve the basic technical effect.

The following description is of the best-contemplated mode of carrying out the disclosure. This description is made for the purpose of illustration of the general principles of the disclosure and should not be taken in a limiting sense. The scope of the disclosure is best determined by reference to the appended claims.

Moreover, the terms “include”, “contain”, and any variation thereof are intended to cover a non-exclusive inclusion. Therefore, a process, method, object, or device that includes a series of elements not only includes these elements, but also includes other elements not specified expressly, or may include inherent elements of the process, method, object, or device. If no more limitations are made, an element limited by “include a/an . . . ” does not exclude other same elements existing in the process, the method, the article, or the device which includes the element.

In the following embodiment, the same reference numerals are used to refer to the same or similar elements throughout the disclosure.

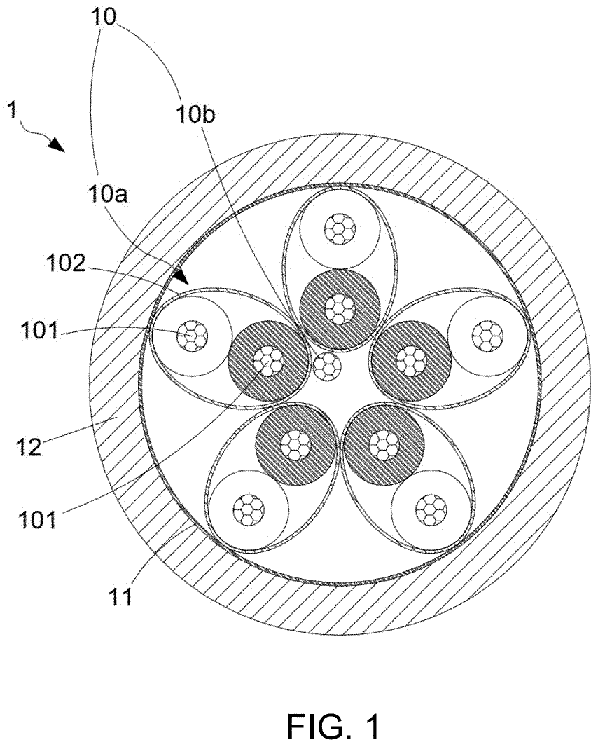

FIG. 1 is a cross-sectional view of a cable of one embodiment of the present disclosure. As shown in the figure, the cable 1 of this embodiment comprises a plurality of conducting wire cores 10 and an electromagnetic shielding layer 11 covering the plurality of conducting wire cores 10. The electromagnetic shielding layer 11 comprises electromagnetic shielding fibers, comprising 100 parts by weight of polyester fiber, 40 to 60 parts by weight of copper, 2 to 10 parts by weight of curing agent, 20 to 30 parts by weight of nickel, 5 to 15 parts by weight of microwave absorber, and 2 to 5 parts by weight of dye. The polyester fiber refers to a polyester melt synthesis and melt spinning. The raw materials for synthetic polyester are polyethylene terephthalate and ethylene glycol, which are majorly obtained from oil cracking or can be obtained from coal and natural gas. The oil is cracked by heating to obtain toluene, xylene, and ethylene, etc. After being chemically processed, terephthalic acid or dimethyl terephthalate and ethylene glycol can be obtained. The polyester melt can be used to prepare polyester chips and melt direct spinning. Polyester chip means the polyester melt to be cast and diced to obtain chips. The curing agent is selected from a group comprising ethylenediamine, diethylenetriamine, triethylenetetramine, and tetraethylenepentamine. The microwave absorber is Fe₃O₄, which generally absorbs X-band and Ku-band frequency waves, presenting a broadband absorption characteristic. In one embodiment, 100 parts by weight of polyester fiber, 40 to 60 parts by weight of copper, 2 to 10 parts by weight of curing agent, 20 to 30 parts by weight of nickel, 5 to 15 parts by weight of microwave absorber, and 2 to 5 parts by weight of dye are first mixed and a plurality of electromagnetic shielding fiber semi-products are manufactured by fiber manufacturing technology of prior art. Then, the plurality of electromagnetic shielding fiber semi-products are placed in the microwave absorber at equal intervals. Thus, each of the electromagnetic shielding fiber semi-products absorbs the microwave absorber uniformly to form electromagnetic shielding fibers.

This is only an embodiment of the present disclosure, which should not be limited thereto.

The cable 1 of this embodiment is majorly applied with an electromagnetic shielding layer 11 made of electromagnetic shielding fibers to replace the electromagnetic shielding layer made of a metal layer and aluminum foil for the conventional cable. Since the electromagnetic shielding fiber of this application performs excellent electromagnetic shielding and heat dissipation, the electromagnetic shielding layer 11 made of electromagnetic shielding fiber can effectively shield the external electromagnetic interference when using the cable 1 of this embodiment. Thus, the cable 1 could keep excellent performance in data and signal transmission. In the present disclosure, the cable 1 having electromagnetic shielding fibers can be applied to high speed connectors, such as SlimSAS, SAS, SFP, USB, Type C, HDMI, Display port and other signal transmission cable products.

In an embodiment, the plurality of conducting wire cores 10 comprises a plurality of signal conducting wire cores 10a and a ground conducting wire core 10b. The plurality of signal conducting wire cores 10a is disposed around the ground conducting wire core 10b. Each of the signal conducting wire core 10a comprises a pair of signal conducting wires 101 and a conductive layer 102. The conductive layer 102 covers the pair of signal conducting wires 101. The signal conducting wire 101 can be made of conventional materials known in the art for cables, such as copper, copper-zinc alloy. The conductive layer 102 is made of metal, such as aluminum foil, aluminum foil Mylar. The ground conducting wire core 10b is a conductor grounding wire, that is, the ground conducting wire core 10b is a conductor. In this embodiment, the number of signal conducting wire core 10a is five, and the number of ground conducting wire core 10b is one. In this embodiment, a cable 1 including five signal conducting wire cores 10a and one ground conducting wire core 10b would be taken as an example for description. However, the cable 1 of the present disclosure may contain a proper number of signal conducting wire cores 10a and ground conducting wire cores 10b. The configuration of the plurality of conducting wire cores 10 described above is only an embodiment of the present disclosure, which should not be limited thereto.

The cable 1 of this embodiment further comprises a protective outer layer 12 which covers the electromagnetic shielding layer 11 to protect the electromagnetic shielding layer 11 and the plurality of conducting wire cores 10. Thus, external moisture and dust can be prevented from entering the cable 1, and the users can be prevented directly contacting with the electromagnetic shielding layer 11 and the plurality of conducting wire cores 10. The protective outer layer 12 is made of insulating material, usually a plastic material such as PVC.

The manufacturing method of the cable 1 of this embodiment is to first provide a plurality of conducting wire cores 10. Next, the electromagnetic shielding layer 11 covers a plurality of conducting wire cores 10, wherein the electromagnetic shielding layer 11 comprises electromagnetic shielding fibers. According to the configuration of the conducting wire core 10 of the present embodiment, the step of providing a plurality of conducting wire cores 10 comprises providing a plurality of signal conducting wire cores 10a and a ground conducting wire core 10b. The plurality of signal conducting wire cores 10a is disposed around the ground conducting wire core 10b. The step of providing the signal conducting wire core 10a further comprises covering a pair of signal conducting wires 101 with a conductive layer 102 to produce the signal conducting wire core 10a. In this embodiment, the preparation of the signal conducting wire core 10a and the ground conducting wire core 10b can be conventional methods in the art. For example, when the signal conducting wire core 10a and the ground conducting wire core 10b are prepared by using a metal blank as raw material, the metal blank can be melted to be a molten liquid. Then shape, roll, stretch and anneale the molten liquid to produce the signal conducting wire core 10a and the ground conducting wire core 10b. For example, when the signal conducting wire core 10a and the ground conducting wire core 10b are prepared by using a copper tube as raw material, steps such as stretching, assembly, firing, tin plating, extrusion, and winding may be included. The configuration of the conducting wire core 10 in the above embodiments is only an embodiment of the present disclosure. So, the configuration of the wire core 10 could be configured in other types. If so, the manufacturing method would be different from the manufacturing method described above.

The material of the electromagnetic shielding layer 11 in the step of covering the plurality of wire cores 10 with the electromagnetic shielding layer 11 is the electromagnetic shielding fiber of this embodiment. The electromagnetic shielding fiber is made by first mixing and blending 100 parts by weight of polyester fiber, 40 to 60 parts by weight of copper, 2 to 10 parts by weight of curing agent, 20 to 30 parts by weight of nickel, 5 to 15 parts by weight of microwave absorber, and 2 to 5 parts by weight of dye and other components, then by conventional fiber manufacturing technology in the art. The step of covering the plurality of conducting wire cores 10 with the electromagnetic shielding layer 11 is first to cover the plurality of conducting wire cores 10 with a plurality of electromagnetic shielding fibers, then curing a plurality of electromagnetic shielding fibers to form an electromagnetic shielding layer 11 covering a plurality of conducting wire cores 10, which is the forming of the electromagnetic shielding layer 11 directly on the plurality of conducting wire cores 10 by electromagnetic shielding fibers.

The electromagnetic shielding layer 11 can also be formed by first applying a plurality of electromagnetic shielding fibers, then covering a plurality of conducting wire cores 10 with the electromagnetic shielding layer 11. Thus, the step of covering the plurality of conducting wire cores 10 with the electromagnetic shielding layer 11 can also be performed by first forming a net-shaped electromagnetic shielding layer 11 by winding or overlapping a plurality of electromagnetic shielding fibers in a molten state, due to which the electromagnetic shielding fibers in the electromagnetic shielding layer 11 are bonded and secured on the overlappings. Then, cool the electromagnetic shielding layer 11. Finally, hot-press the electromagnetic shielding layer 11 onto the plurality of conducting wire cores 10. Thus, the electromagnetic shielding layer 11 covers the plurality of conducting wire cores 10. Alternatively, the step of covering the plurality of conducting wire cores 10 with the electromagnetic shielding layer 11 can be performed by first forming a net-shaped electromagnetic shielding layer 11 by overlapping a plurality of electromagnetic shielding fibers in a cooled state. Then, hot-melt and secure the electromagnetic shielding fibers of the electromagnetic shielding layer 11 on the overlappings. Finally, hot-press the electromagnetic shielding layer 11 onto the plurality of conducting wire cores 10. Thus, the electromagnetic shielding layer 11 covers the plurality of conducting wire cores 10.

In one embodiment, after the step of covering the plurality of conducting wire cores 10 with the electromagnetic shielding layer 11, a protective outer layer 12 is formed on the electromagnetic shielding layer 11. In this embodiment, the protective outer layer 12 could be formed on the electromagnetic shielding layer 11 through a conventional method in the art, for example, by extrusion.

### Performance Test

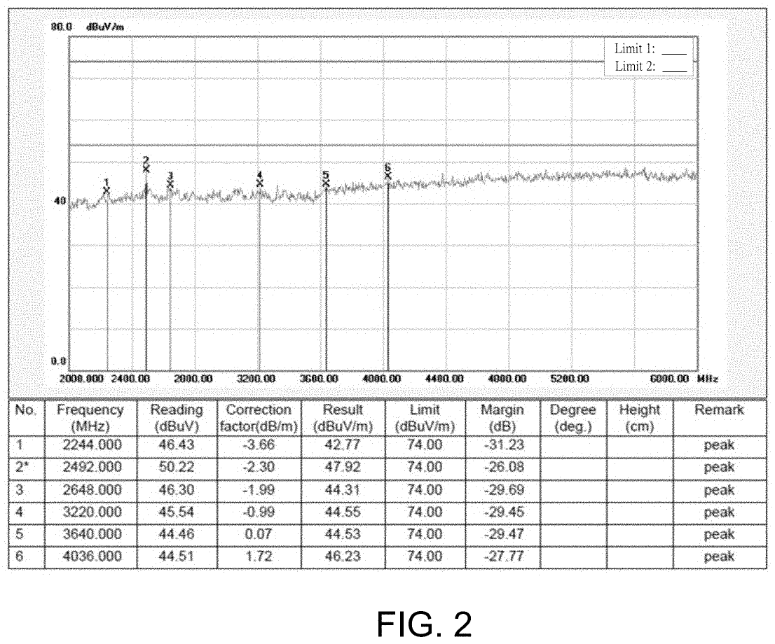

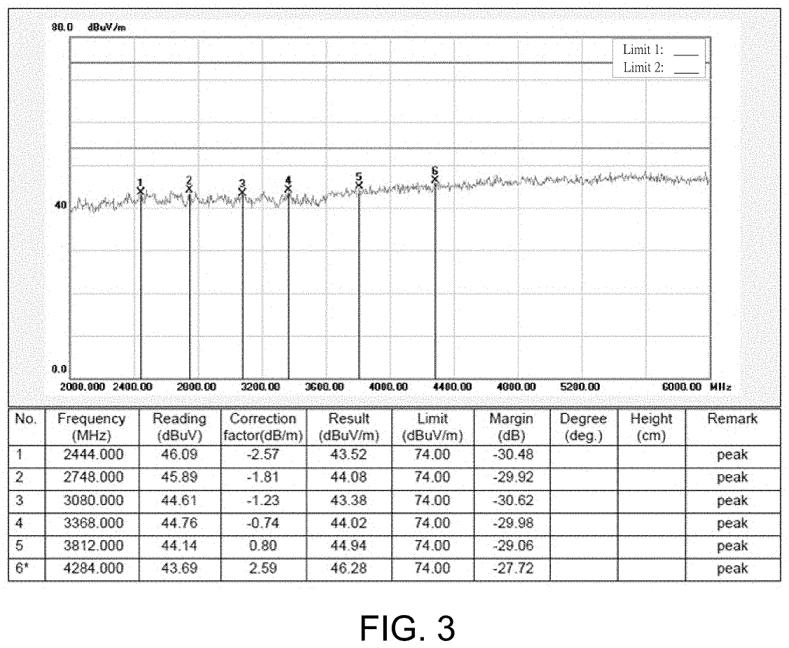

FIG. 2 is an electromagnetic shielding test chart of the prior art. FIG. 3 is an electromagnetic shielding test chart of a cable of one embodiment of the present disclosure.

FIG. 2 shows the result of performing an electromagnetic shielding test by replacing the cable-type electromagnetic shielding layer of this embodiment to the conventional cable-type electromagnetic shielding layer (metal layer and aluminum foil). FIG. 3 shows the result of the electromagnetic shielding test on the cable of this embodiment. The X axis in FIG. 2 and FIG. 3 represents the electromagnetic wave frequency and the Y axis represents the electromagnetic wave intensity. As shown in FIG. 2 and FIG. 3, in the frequency range of 30 MHz-1000 MHz, the cable having the electromagnetic shielding layer (metal layer and aluminum foil) produces a peak with a peak value greater than 50 dBuV at a frequency of 2492 MHz. In this embodiment, the peak value falls between 44 dBuV-46 dBuV as the cable having the electromagnetic shielding layer comprising electromagnetic shielding fiber. Therefore, in the frequency range of 30 MHz˜1000 MHz, the electromagnetic shielding performance of the cable having the electromagnetic shielding fiber of the present disclosure is obviously superior to the cable having the conventional electromagnetic shielding layer (metal layer and aluminum foil).

In summary, the present disclosure provides a cable electromagnetic shielding fiber, a cable, and a cable manufacturing method. The electromagnetic shielding fiber of this disclosure performs excellent electromagnetic shielding and heat dissipation. The cable having the electromagnetic shielding layer made of the electromagnetic shielding layer of the present disclosure performs great electromagnetic shielding and of data and signal transmission.

It is to be understood that the term “comprises”, “comprising”, or any other variants thereof, is intended to encompass a non-exclusive inclusion, such that a process, method, article, or device of a series of elements not only comprise those elements but also comprises other elements that are not explicitly listed, or elements that are inherent to such a process, method, article, or device. An element defined by the phrase “comprising a . . . ” does not exclude the presence of the same element in the process, method, article, or device that comprises the element.

Although the present disclosure has been explained in relation to its preferred embodiment, it does not intend to limit the present disclosure. It will be apparent to those skilled in the art having regard to this present disclosure that other modifications of the exemplary embodiments beyond those embodiments specifically described here may be made without departing from the spirit of the disclosure. Accordingly, such modifications are considered within the scope of the disclosure as limited solely by the appended claims.

1. An electromagnetic shielding fiber, comprising:
100 parts by weight of polyester fiber;
40 to 60 parts by weight of copper;
2 to 10 parts by weight of curing agent;
20 to 30 parts by weight of nickel;
5 to 15 parts by weight of microwave absorber; and
2 to 5 parts by weight of dye.

2. The electromagnetic shielding fiber according to claim 1, wherein the curing agent is selected from a group comprising ethylenediamine, diethylenetriamine, triethylenetetramine, and tetraethylenepentamine.

3. The electromagnetic shielding fiber according to claim 1, wherein the microwave absorber is Fe₃O₄.

4. A cable, comprising:
a plurality of conducting wire cores; and
an electromagnetic shielding layer covering the plurality of conducting wire cores, the electromagnetic shielding layer comprising the electromagnetic shielding fiber comprising:
100 parts by weight of polyester fiber;
40 to 60 parts by weight of copper;
2 to 10 parts by weight of curing agent;
20 to 30 parts by weight of nickel;
5 to 15 parts by weight of microwave absorber; and
2 to 5 parts by weight of dye.

5. The electromagnetic shielding fiber according to claim 4, wherein the curing agent is selected from a group comprising ethylenediamine, diethylenetriamine, triethylenetetramine, and tetraethylenepentamine.

6. The electromagnetic shielding fiber according to claim 4, wherein the microwave absorber is Fe₃O₄.

7. The cable according to claim 4, wherein the plurality of conducting wire cores comprises a plurality of signal conducting wire cores and a ground conducting wire core; the plurality of the signal conducting wire cores are disposed around the ground conducting wire core.

8. The cable according to claim 7, wherein each of the signal conducting wire cores comprises a pair of signal conducting wires and a conductive layer covering the pair of signal conducting wires.

9. The cable according to claim 7, wherein the ground conducting wire core is a conductor grounding wire.

10. The cable according to claim 4 further comprises a protective outer layer covering the electromagnetic shielding layer.

11. A cable manufacturing method, comprising:
providing a plurality of conducting wire cores; and
covering the plurality of conducting wire cores by an electromagnetic shielding layer, the electromagnetic shielding layer comprising the electromagnetic shielding fiber comprising:
100 parts by weight of polyester fiber;
40 to 60 parts by weight of copper;
2 to 10 parts by weight of curing agent;
20 to 30 parts by weight of nickel;
5 to 15 parts by weight of microwave absorber; and
2 to 5 parts by weight of dye.

12. The electromagnetic shielding fiber according to claim 11, wherein the curing agent is selected from a group comprising ethylenediamine, diethylenetriamine, triethylenetetramine, and tetraethylenepentamine.

13. The electromagnetic shielding fiber according to claim 11, wherein the microwave absorber is Fe₃O₄.

14. The cable manufacturing method according to claim 11, wherein the steps of the electromagnetic shielding layer covering the plurality of conducting wire cores comprising:
winding or overlapping the plurality of electromagnetic shielding fibers to cover the plurality of conducting wire cores; and
curing the plurality of electromagnetic shielding fibers to form the electromagnetic shielding layer.

15. The cable manufacturing method according to claim 11, wherein the steps of the electromagnetic shielding layer covering the plurality of conducting wire cores comprising:
providing the electromagnetic shielding layer formed by the plurality of the electromagnetic shielding fibers; and
hot pressing the electromagnetic shielding layer on the plurality of conducting wire cores.

16. The cable manufacturing method according to claim 15, wherein the step of providing the electromagnetic shielding layer formed by the plurality of the electromagnetic shielding fibers comprising:
winding or overlapping the plurality of electromagnetic shielding fibers under a molten state to form the electromagnetic shielding layer.

17. The cable manufacturing method according to claim 15, wherein the step of providing the electromagnetic shielding layer formed by the plurality of the electromagnetic shielding fibers comprising:
winding or overlapping the plurality of electromagnetic shielding fibers under a cooled state to form the electromagnetic shielding layer.

18. The cable manufacturing method according to claim 11 further comprises the forming of a protective outer layer on the electromagnetic shielding layer after the step of covering the plurality of conducting wire cores with the electromagnetic shielding layer.
